(19) United States
(12) Patent Application Publication
(10) Pub. No.: US 2026/0282931 A1
(43) Pub. Date: Sep. 17, 2026

(54) ELECTROMAGNETIC COMPARTMENTAL SHIELDING FOR MULTICHIP CAVITY SYSTEM-IN-PACKAGE (SIP) MODULE

(71) Applicant: Qorvo US, Inc., Greensboro, NC (US)

(72) Inventor: MD Hasnine, Wylie, TX (US)

(21) Appl. No.: 19/406,318

(22) Filed: Dec. 2, 2025

Related U.S. Application Data
(60) Provisional application No. 63/770,035, filed on Mar. 11, 2025.

(51) Int. Cl. H10W 42/20; H10W 40/20; H10W 76/01; H10W 76/12; H10W 76/63; H10W 90/00; H10W 90/10

(52) U.S. Cl. CPC H10W 42/273; H10W 40/233; H10W 76/01; H10W 76/167; H10W 76/63; H10W 90/10; H10W 90/754; H10W 42/281

(57) ABSTRACT

Aspects of the disclosure provide a semiconductor package and a method of producing the same. The disclosed semiconductor package includes a laminate; a plurality of wire bond dies attached to the laminate; and a lid attached to the laminate via a lid seal epoxy, the lid comprising a plurality of compartments configured to encase the plurality of wire bond dies and form cavities with each cavity encapsulating a wire bond die. In various embodiments, each compartment may include a first wall that is coated with an electromagnetic shielding material and a second wall that is free of the material coated on the first wall. In various embodiments, the lid may include a vent hole configured to release vapor pressure during attachment of the lid to the laminate. In various embodiments, a wireless device includes the disclosed semiconductor package.

### CROSS-REFERENCE TO RELATED APPLICATION

This application claims priority to U.S. Patent Application No. 63/770,035, filed Mar. 11, 2025, all of which is incorporated by reference herein in its entirety.

### TECHNICAL FIELD

The present disclosure relates generally to electromagnetic shielding in electronic packages, and in particular, relates to a semiconductor package and a method for making a semiconductor package having a multichip system-in-package cavity module with electromagnetic interference shielding.

### BACKGROUND

Advanced semiconductor electronics are typically assembled using cutting-edge manufacturing techniques. As electronic systems become more compact and engineered to operate at higher frequencies, issues related to electromagnetic interference (EMI) become more prominent and pronounced, resulting in performance degradation that leads to signal integrity issues and even component failures. In current high-density electronic circuits, EMI can degrade signal integrity, leading to errors and reduced performance. Existing shielding methods are often bulky, costly, or insufficient in effectively managing EMI in compact spaces. In high-frequency applications, when multiple chips are placed in close proximity, even if not electrically connected, electromagnetic fields from one chip can interfere with neighboring chips, causing crosstalk. This interference can lead to signal degradation, data corruption, and overall system instability. In some instances, the unwanted coupling of signals caused by EMI from one system or circuit to another can affect signal integrity by causing delays in signal transmission.

Laminate cavity packages are used in radio frequency (RF) applications due to air's superior dielectric properties compared to mold compound-based packages, offering significant RF performance advantages. These packages typically use plastic lids. Additionally, multichip system-in-package (SiP) modules are widely used in high-frequency RF applications, such as radar and telecommunications. While plastic lids protect the module from environmental factors, they do not shield the circuits from EMI with one another. Thus, there is a need for a system and a method for preparing a semiconductor package with improved electromagnetic isolation in electronic devices that can enhance the electromagnetic performance of multichip SiP cavity modules.

### SUMMARY

Embodiments of the present disclosure include advanced semiconductor packaging techniques with electromagnetic shielding capabilities designed for wide band gap semiconductor packages. Aspects of the disclosure advantageously provide a semiconductor package and one or more methods of making a semiconductor package having a multichip system-in-package (SIP) cavity module with electromagnetic interference shielding.

In an exemplary aspect, a semiconductor package is provided. The semiconductor package includes a laminate; a plurality of wire bond dies attached to the laminate; and a lid attached to the laminate via a lid seal epoxy, the lid comprising a plurality of compartments configured to encase the plurality of wire bond dies, wherein the plurality of compartments form cavities with each cavity encapsulating a wire bond die of the plurality of wire bond dies.

In one or more embodiments, each of the plurality of compartments includes a first wall that is coated with an electromagnetic shielding material. In one or more embodiments, each of the plurality of compartments includes a second wall that is free of the electromagnetic shielding material coated on the first wall. In one or more embodiments, the electromagnetic shielding material may include Ag, Cu, Ni, Al, or a combination thereof.

In one or more embodiments, the plurality of compartments includes at least one divider that is attached to the laminate via an electrically conductive epoxy to form a cavity that provides a moisture sealed environment that meets a moisture sensitivity level (MSL), a gross leak (GL) standard, or a combination thereof. In one or more embodiments, the lid may include a vent hole configured to release vapor pressure during attachment of the lid to the laminate. In one or more embodiments, the lid may include a flame-retardant FR4 material. In one or more embodiments, the laminate may include a plated heat spreader.

In one or more embodiments, a wireless device may include the semiconductor package as disclosed herein.

In an exemplary aspect, a method for producing a semiconductor package is provided. The method includes forming a lid comprising a plurality of compartments; attaching a plurality of wire bond dies to a laminate; and attaching the lid to the laminate via a lid seal epoxy such that the plurality of compartments form cavities with each cavity encapsulating a wire bond die of the plurality of wire bond dies.

In one or more embodiments of the method, forming the lid may include coating an electromagnetic shielding material on a first wall of each of the plurality of compartments. In one or more embodiments, each of the plurality of compartments includes a second wall that is free of the electromagnetic shielding material coated on the first wall. In one or more embodiments, the electromagnetic shielding material comprises Ag, Cu, Ni, Al, or a combination thereof.

In one or more embodiments of the method, attaching the lid to the laminate may further include attaching at least one divider of the plurality of compartments to the laminate via an electrically conductive epoxy to form a cavity that provides a moisture sealed environment that meets a moisture sensitivity level (MSL), a gross leak (GL) standard, or a combination thereof. In one or more embodiments, the lid may include a vent hole configured to release vapor pressure during attachment of the lid to the laminate. In one or more embodiments, the lid may include a flame-retardant FR4 material. In one or more embodiments, the laminate may include a plated heat spreader.

In one or more embodiments, a wireless device may include the semiconductor package produced via the method as disclosed herein.

In an exemplary aspect, a wireless device is provided. The wireless device may include a semiconductor package, which includes a plurality of wire bond dies attached to a laminate comprising a plated heat spreader, and a fire-retardant lid attached to the laminate via a lid seal epoxy, wherein the fire-retardant lid comprises a plurality of compartments configured to encase the plurality of wire bond dies, and wherein the plurality of compartments form cavities with each cavity encapsulating a wire bond die of the plurality of wire bond dies.

In one or more embodiments of the wireless device, each of the plurality of compartments includes a first wall that is coated with an electromagnetic shielding material and a second wall that is free of the electromagnetic shielding material coated on the first wall. In one or more embodiments, the electromagnetic shielding material may include Ag, Cu, Ni, Al, or a combination thereof.

In one or more embodiments of the wireless device, the plurality of compartments includes at least one divider that is attached to the laminate via an electrically conductive epoxy to form a cavity that provides a moisture sealed environment that meets a moisture sensitivity level (MSL), a gross leak (GL) standard, or a combination thereof. In one or more embodiments, the fire-retardant lid may include a vent hole configured to release vapor pressure during attachment of the lid to the laminate. In one or more embodiments, the fire-retardant lid may include an FR4 material.

Additional aspects, embodiments, implementations, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1A illustrates a cross-sectional view of an example semiconductor package, according to aspects of the present disclosure.

FIG. 1B illustrates a cross-sectional view of the lid of the example semiconductor package of FIG. 1A, according to aspects of the present disclosure.

FIG. 1C illustrates a bottom view of the lid of the example semiconductor package of FIG. 1A, according to aspects of the present disclosure.

FIG. 1D illustrates a top view of the laminate of the example semiconductor package of FIG. 1A, according to aspects of the present disclosure.

FIG. 2 illustrates a flowchart for a method for producing a semiconductor package, according to aspects of the present disclosure.

FIG. 3 illustrates an electronic device or a wireless device comprising a semiconductor package, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

Embodiments of the present disclosure include advanced semiconductor manufacturing methodologies for preparing a semiconductor package having a multichip system-in-package (SIP) cavity module with electromagnetic interference (EMI) shielding. The disclosed semiconductor package may include an EMI shielding in compartments that encase individual dies disposed on a laminate in one or more areas of the semiconductor package. The disclosed EMI shielding in the SIP module aims to increase isolation between individual dies or radio frequency (RF) devices within the semiconductor package, thereby mitigating electromagnetic interference and crosstalk, which are common issues in densely packed electronic circuits. The disclosed EMI shielding approach can help improve isolation between these devices or between different function blocks, ensuring that each device operates within its designated electromagnetic environment, thus improving overall system performance and reliability.

In various embodiments disclosed herein, a fire-retardant lid, such as but not limited to a lid made from FR4 material, is processed to form compartments within the lid. The compartments within the lid have walls that are coated with EMI shielding materials, such as silver (Ag), copper (Cu), nickel (Ni), or aluminum (Al), etc. The shielding materials can help isolate the RF signals generated by the electronic components within the compartments. During FR4 lid fabrication, the process involves cavity routing to form one or more compartmental walls, followed by coating of the EMI shield materials on the walls and selectively etching the shielding material from one or more of the walls (typically to allow transmission of the RF signals generated by an electronic component) in each of the compartments. During the lid attachment process, lid sealing epoxy is used to attach the outer walls of the lid to the multichip SiP substrate while inner walls (with EMI shield coating) are attached to the substrate using an electrically conductive epoxy to ground the shield/inner wall, which results in a cavity structure with selective compartmental shielding for the multichip SiP module. This disclosed approach effectively shields the circuit in each of the compartments from interference, preventing crosstalk and isolating different functional blocks within the SiP module of the semiconductor package.

It is known that plastic cavity packages are vulnerable to gross leak testing under environmental conditions like moisture sensitivity level (MSL) pre-conditioning. During board-level assembly, the cavity package may undergo multiple reflows and aqueous washes, and liquid can enter the module if they are not gross leak (GL) compliant, in some embodiments. As disclosed herein, the fabricated lid may have multiple walls and thus may increase adhesion with the substrate. This can help reduce chip-package interaction and prevent warpage, enhancing the GL integrity of the cavity structure suitable for used in a multichip SiP semiconductor cavity module with integrated EMI shielding capabilities.

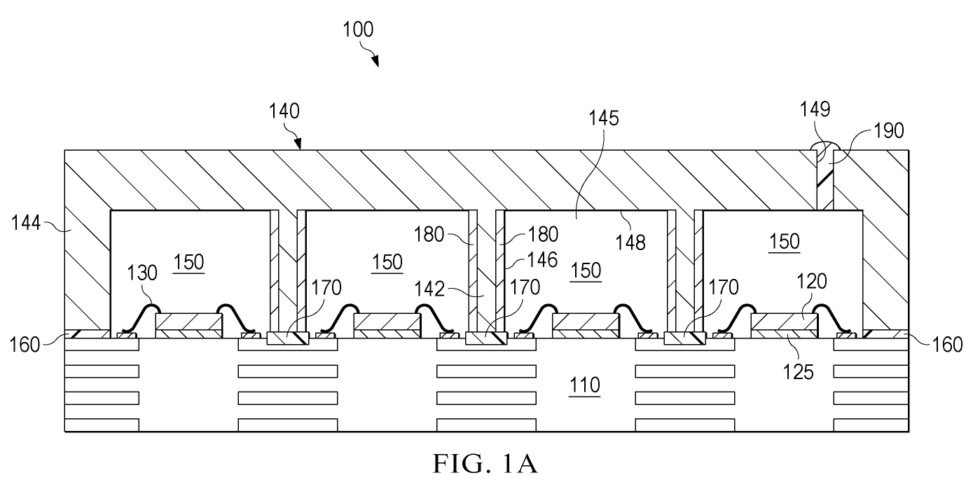

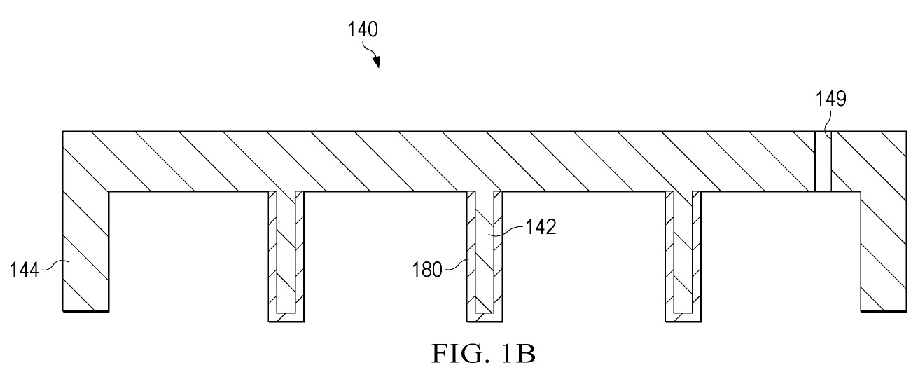

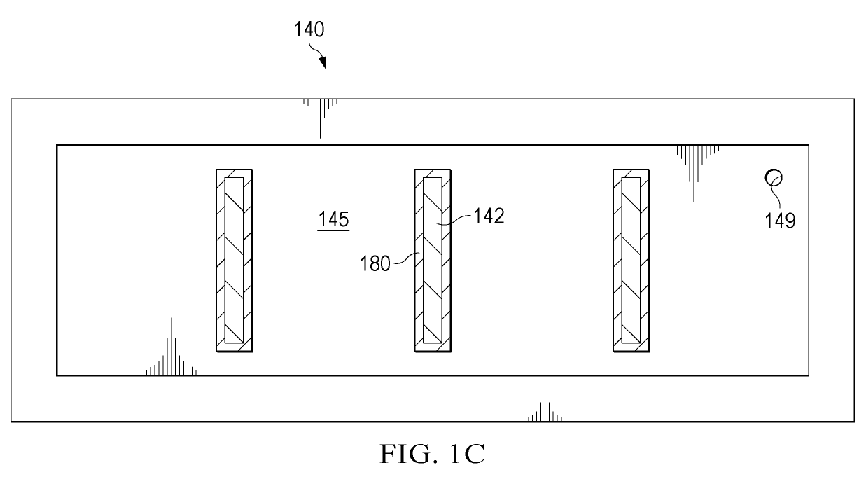

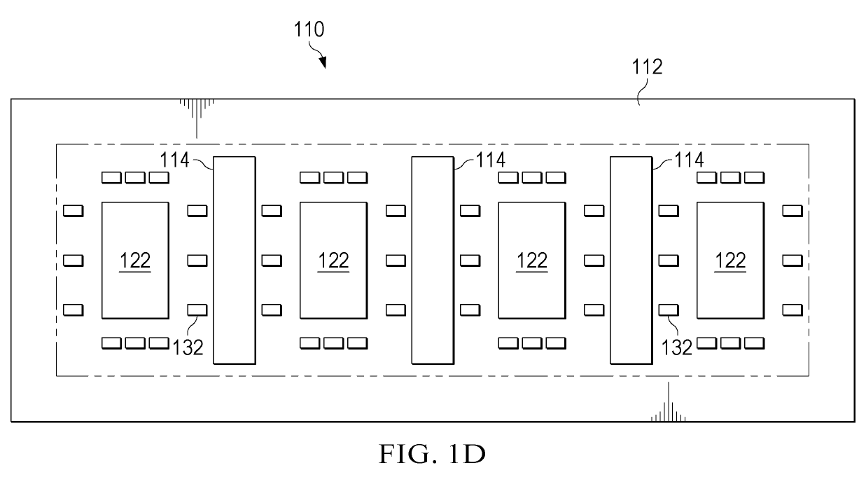

To further demonstrate the disclosed semiconductor package and methods for preparing such packages, various embodiments of packages and preparation methodologies are described below in further detail with respect to the FIGS. 1-3.

FIGS. 1A, 1B, 1C and 1D, illustrate various views of an example semiconductor package 100 and its components, according to aspects of the present disclosure. In particular, FIG. 1A illustrates a cross-sectional view of the semiconductor package 100, FIG. 1B illustrates a cross-sectional view of a lid 140 of the semiconductor package of 100, FIG. 1C

illustrates a bottom view of the lid 140, and FIG. 1D illustrates a top view of a laminate 110 of the semiconductor package 100, according to aspects of the present disclosure. In one or more embodiments, the semiconductor package 100 described with respect to FIGS. 1A, 1B, 1C and 1D, may include a wide band gap semiconductor package with a multichip system-in-package (SIP) cavity module with electromagnetic interference shielding. In some embodiments, the semiconductor package 100 may be produced or manufactured using advanced semiconductor packaging techniques as disclosed herein.

As illustrated in FIGS. 1A, 1B, 1C and 1D, the semiconductor package 100 may include a laminate 110 (may also be referred to herein as a substrate) and a plurality of wire bond dies 120, which are attached to the laminate 110 via a die attach material 125. In one or more embodiments, the laminate 110 may include a plated heat spreader, or other suitable laminated substrate. As depicted in FIG. 1A, the semiconductor package 100 also includes wire bonds 130, which electrically connect the wire bond dies 120 to the laminate 110.

The semiconductor package 100 further includes a lid 140, which is attached to the laminate 110. In one or more embodiments, the lid 140 may include a flame-retardant material, such as FR4 material. As shown in the cross-sectional view of FIG. 1A, the lid 140 includes a plurality of compartments 145 that are formed by having one or more dividers 142 (also referred to herein as inner walls 142) formed inside the lid 140. These dividers 142 are built into the lid 140 and are configured to encase the plurality of wire bond dies 120 when the lid 140 is attached to the laminate 110. Thus, the plurality of compartments 145 of the lid 140 form cavities 150 when the lid 140 is attached to the laminate 110, where each cavity 150 encapsulates a wire bond die 120 of the plurality of wire bond dies 120, as illustrated in FIG. 1A.

Furthermore, the lid 140 is attached to the laminate 110 via the lid 140’s outer walls 144 using a lid seal epoxy 160, as shown in FIG. 1A. Similarly, the inner walls/dividers 142 are attached to the laminate 110 via an electrically conductive epoxy 170, as shown in FIG. 1A. In various embodiments, the lid seal epoxy 160 may include a low modulus adhesive with a pressure rating from about 2 megapascal (MPa) to about 20 MPa. In various embodiments, the electrically conductive epoxy 170 may include an electrically conductive high modulus adhesive with a pressure rating from about 1 gigapascal (GPa) to about 3 GPa.

In various embodiments, the high modulus electrically conductive epoxy 170 can hold the attached lid/laminate module (i.e., SiP module) and resist deflection, reducing interface delamination. In various embodiments, the low modulus lid seal epoxy 160 used on the outer walls 144 (i.e., wall on the perimeter of the lid 140/laminate 110) can accommodate large deflections with higher strain. Its flexibility allows it to handle significant deflection without delamination, improving chip-package interaction. Thus, in various embodiments, the lid seal epoxy 160 and the electrically conductive epoxy 170 used to form the cavities 150 enable a moisture sealed environment of the semiconductor package 100 that meets a moisture sensitivity level (MSL), a gross leak (GL) standard, or a combination thereof.

As further depicted in FIG. 1A, each of the plurality of compartments 145 includes a first wall 146 (also referred to as “side wall 146” or “compartmental wall 146”) that is coated with an electromagnetic shielding material 180. In one or more embodiments, each of the plurality of compartments 145 may also include a second wall 148 (also referred to herein as “top wall 148”) that is free of the electromagnetic shielding material, as depicted in FIG. 1A. The lack of the electromagnetic shielding coating on the second wall 148 allows transmission of the radio frequency signals generated by the dies 120, in accordance with one or more embodiments. Similarly, the electromagnetic shielding material coating on the first wall 146 prevents or eliminates the crosstalk or electromagnetic interference between adjacent dies 120, in accordance with one or more embodiments. In one or more embodiments, the electromagnetic shielding material 180 may include Ag, Cu, Ni, Al, or a combination thereof.

As further illustrated in FIG. 1A, the lid 140 may include a vent hole 149 configured to release vapor pressure during attachment of the lid 140 to the laminate 110. In one or more embodiments, the vent hole 149 can be filled with an epoxy 190 once vapor pressure subsided during the attachment process. FIG. 1B illustrates the lid 140 prior to attachment to the laminate 110, depicting a vent hole without the epoxy material 190 filled in.

FIG. 1C illustrates a bottom view of the lid 140, depicting the dividers/inner walls 142 dividing compartments 145. FIG. 1D illustrates a top view of the laminate 110 prior to attachment of the lid 140. As illustrated in FIG. 1D, the laminate 110 includes die attached pads 122 configured for attaching the dies 120, wire bond pads 132 configured for attaching the wire bonds 130, perimeter wall land pads 112 configured for attaching the outer walls 144 using the lid seal epoxy 160, and compartment shielding wall land pads 114 configured for attaching the dividers/inner walls 142 using the electrically conductive epoxy 170.

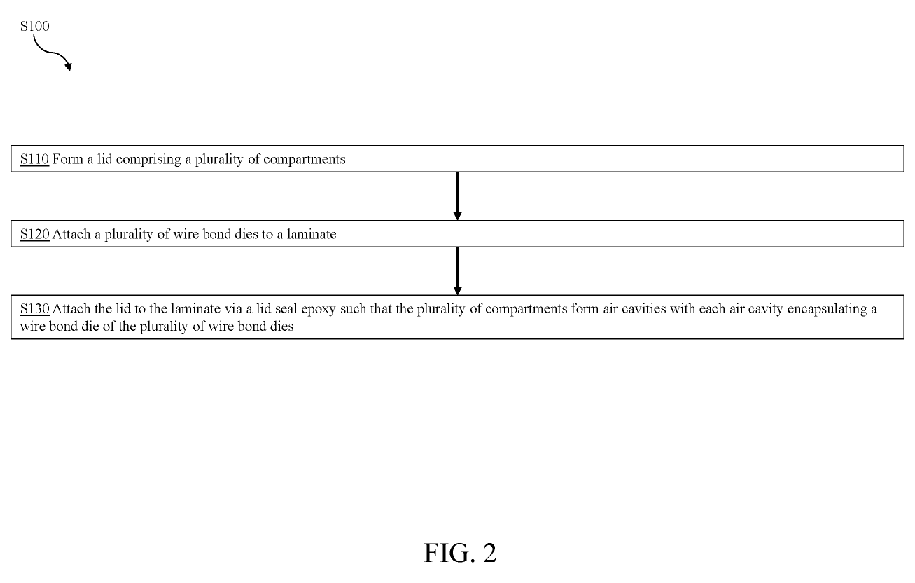

FIG. 2 illustrates a flowchart for a method S100 for producing an example semiconductor package, according to aspects of the present disclosure. In one or more embodiments, the semiconductor package formed via the method S100 may include a semiconductor package having a multichip system-in-package (SIP) cavity module with electromagnetic interference (EMI) shielding, such as the semiconductor package 100 as described with respect to FIGS. 1A, 1B, 1C and 1D, .

As shown in FIG. 2, the method S100 includes, at step S110, forming a lid comprising a plurality of compartments; at step S120, attaching a plurality of wire bond dies to a laminate; and at step S130, attaching the lid to the laminate via a lid seal epoxy such that the plurality of compartments form cavities with each cavity encapsulating a wire bond die of the plurality of wire bond dies.

In one or more embodiments of the method S100, the laminate includes a laminate, such as the laminate 110, the plurality of dies includes a plurality of wire bond dies, such as the plurality of wire bond dies 120, the lid may include a lid, such as the lid 140, the plurality of compartments may include a plurality of compartments, such as the plurality of compartments 145, the cavities may include cavities, such as the cavities 150, the lid seal epoxy may include a lid seal epoxy, such as the lid seal epoxy 160, as described with respect to FIGS. 1A, 1B, 1C and 1D, . In one or more embodiments, the laminate may also be referred to herein as a substrate and may include a plated heat spreader, or other suitable laminated substrate. In one or more embodiments, the lid may include a flame-retardant material, such as FR4 material.

In one or more embodiments of the method S100, forming the lid may include coating an electromagnetic shielding material on a first wall of each of the plurality of compartments. In one or more embodiments of the method S100, each of the plurality of compartments includes a second wall that is free of the electromagnetic shielding material coated on the first wall. In one or more embodiments, the electromagnetic shielding material includes an electromagnetic shielding material, such as the electromagnetic shielding material 180, the first wall includes a first wall, such as the first wall 146, the second wall includes a second wall, such as the second wall 148, as described with respect to FIGS. 1A, 1B, 1C and 1D, . In one or more embodiments, the electromagnetic shielding material comprises Ag, Cu, Ni, Al, or a combination thereof.

In one or more embodiments of the method S100, attaching the lid to the laminate may further include attaching at least one divider of the plurality of compartments to the laminate via an electrically conductive epoxy to form a cavity that provides a moisture sealed environment that meets a moisture sensitivity level (MSL), a gross leak (GL) standard, or a combination thereof. In one or more embodiments, the lid may include a vent hole configured to release vapor pressure during attachment of the lid to the laminate. In one or more embodiments, the at least one divider includes a divider, such as the dividers 142, the electrically conductive epoxy includes a electrically conductive epoxy, such as the electrically conductive epoxy 170, the vent hole includes a vent hole, such as the vent hole 149, as described with respect to FIGS. 1A, 1B, 1C and 1D, .

In one or more embodiments, a wireless device may include the semiconductor package produced via the method S100 as disclosed herein.

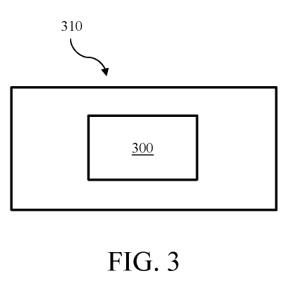

FIG. 3 illustrates an electronic device or a wireless device 310 comprising a semiconductor package 300, according to aspects of the present disclosure. In some implementations, the electronic device or wireless device 310 may include, for example, but not limited to, a computer, a cellular device, a satellite communication device, a wi-fi device, a radar, a global position system device, or any electronic device. In one or more embodiments, the semiconductor package 300 may be produced in accordance with the method S100 described with respect to FIG. 2, and/or may include a semiconductor package having a multichip system-in-package (SIP) cavity module with electromagnetic interference (EMI) shielding, such as the semiconductor package 100, as described with respect to FIGS. 1A, 1B, 1C and 1D, . The semiconductor package may implement any RF circuitry used in wireless applications, as an example, such as one or more RF power amplifiers; and the semiconductor package may be coupled to other circuitry for implementing a wireless application, such as a baseband processor or other types of processors.

In one or more embodiments, the wireless device 310 may include the semiconductor package 300. In one or more embodiments, the semiconductor package 300 includes a plurality of wire bond dies, such as wire bond dies 120, attached to a laminate, such as laminate 110, comprising a plated heat spreader, and a fire-retardant lid, such as lid 140, attached to the laminate via a lid seal epoxy, such as lid seal epoxy 160, wherein the fire-retardant lid comprises a plurality of compartments, such as compartments 145, configured to encase the plurality of wire bond dies, and wherein the plurality of compartments form cavities, such as cavities 150, with each cavity encapsulating a wire bond die of the plurality of wire bond dies.

In one or more embodiments of the wireless device 310, each of the plurality of compartments includes a first wall, such as first wall 146, that is coated with an electromagnetic shielding material, such as the electromagnetic shielding material 180, and a second wall, such as second wall 148, that is free of the electromagnetic shielding material coated on the first wall. In one or more embodiments, the electromagnetic shielding material may include Ag, Cu, Ni, Al, or a combination thereof.

In one or more embodiments of the wireless device 310, the plurality of compartments includes at least one divider, such as divider 142, that is attached to the laminate via an electrically conductive epoxy, such as electrically conductive epoxy 170, to form a cavity that provides a moisture sealed environment that meets a moisture sensitivity level (MSL), a gross leak (GL) standard, or a combination thereof. In one or more embodiments, the fire-retardant lid may include a vent hole, such as vent hole 149, configured to release vapor pressure during attachment of the lid to the laminate. In one or more embodiments, the fire-retardant lid may include an FR4 material.

In one or more embodiments, the semiconductor package 300 of the wireless device 310 may be produced via the method S100, as described with respect to FIG. 2.

Various embodiments of the disclosure advantageously provide a semiconductor package, such as the semiconductor packages 100 and 300, as described with respect to FIGS. 1A, 1B, 1C, 1D and 3, and a method, such as the method S100, as described with respect to FIG. 2, of producing a semiconductor package having a multichip system-in-package (SIP) cavity module with electromagnetic interference shielding.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. A semiconductor package, comprising:
a laminate;
a plurality of wire bond dies attached to the laminate; and
a lid attached to the laminate via a lid seal epoxy, the lid comprising a plurality of compartments configured to encase the plurality of wire bond dies,
wherein the plurality of compartments form cavities with each cavity encapsulating a wire bond die of the plurality of wire bond dies.

2. The semiconductor package of claim 1, wherein each of the plurality of compartments includes a first wall that is coated with an electromagnetic shielding material.

3. The semiconductor package of claim 2, wherein each of the plurality of compartments includes a second wall that is free of the electromagnetic shielding material coated on the first wall.

4. The semiconductor package of claim 2, wherein the electromagnetic shielding material comprises Ag, Cu, Ni, Al, or a combination thereof.

5. The semiconductor package of claim 1, wherein the plurality of compartments includes at least one divider that is attached to the laminate via an electrically conductive epoxy to form a cavity that provides a moisture sealed environment that meets a moisture sensitivity level (MSL), a gross leak (GL) standard, or a combination thereof.

6. The semiconductor package of claim 1, wherein the lid further comprises a vent hole configured to release vapor pressure during attachment of the lid to the laminate.

7. The semiconductor package of claim 1, wherein:
the lid comprises a flame-retardant FR4 material;
the laminate comprises a plated heat spreader; or
both.

8. A wireless device comprising the semiconductor package of claim 1.

9. A method for producing a semiconductor package, comprising:
forming a lid comprising a plurality of compartments;
attaching a plurality of wire bond dies to a laminate; and
attaching the lid to the laminate via a lid seal epoxy such that the plurality of compartments form cavities with each cavity encapsulating a wire bond die of the plurality of wire bond dies.

10. The method of claim 9, wherein forming the lid comprises coating an electromagnetic shielding material on a first wall of each of the plurality of compartments.

11. The method of claim 10, wherein each of the plurality of compartments includes a second wall that is free of the electromagnetic shielding material coated on the first wall.

12. The method of claim 10, wherein the electromagnetic shielding material comprises Ag, Cu, Ni, Al, or a combination thereof.

13. The method of claim 9, wherein attaching the lid to the laminate further comprises attaching at least one divider of the plurality of compartments to the laminate via an electrically conductive epoxy to form a cavity that provides a moisture sealed environment that meets a moisture sensitivity level (MSL), a gross leak (GL) standard, or a combination thereof.

14. The method of claim 9, wherein the lid further comprises a vent hole configured to release vapor pressure during attachment of the lid to the laminate.

15. The method of claim 14, wherein:
the lid comprises a flame-retardant FR4 material;
the laminate comprises a plated heat spreader; or
both.

16. A wireless device comprising:
a semiconductor package comprising a plurality of wire bond dies attached to a laminate comprising a plated heat spreader, and a fire-retardant lid attached to the laminate via a lid seal epoxy,
wherein the fire-retardant lid comprises a plurality of compartments configured to encase the plurality of wire bond dies, and
wherein the plurality of compartments form cavities with each cavity encapsulating a wire bond die of the plurality of wire bond dies.

17. The wireless device of claim 16, wherein each of the plurality of compartments includes a first wall that is coated with an electromagnetic shielding material and a second wall that is free of the electromagnetic shielding material coated on the first wall.

18. The wireless device of claim 16, wherein the electromagnetic shielding material comprises Ag, Cu, Ni, Al, or a combination thereof.

19. The wireless device of claim 16, wherein the plurality of compartments includes at least one divider that is attached to the laminate via an electrically conductive epoxy to form a cavity that provides a moisture sealed environment that meets a moisture sensitivity level (MSL), a gross leak (GL) standard, or a combination thereof.

20. The wireless device of claim 16, wherein the fire-retardant lid further comprises a vent hole configured to release vapor pressure during attachment of the lid to the laminate.
